(19) United States
(12) Patent Application Publication
(10) Pub. No.: US 2025/0226265 A1
(43) Pub. Date: Jul. 10, 2025

(54) CORRECTING OF DESIGN AND MASK SHAPE POSITION DUE TO DIE AND WAFER DISTORTION FOR BONDING

(71) Applicant: Tokyo Electron Limited, Tokyo (JP)

(72) Inventors: Dave POWER, Albany, NY (US); David CONKLIN, Saratoga Springs, NY (US); Anthony SCHEPIS, Averill Park, NY (US)

(73) Assignee: Tokyo Electron Limited, Tokyo (JP)

(21) Appl. No.: 18/404,489

(22) Filed: Jan. 4, 2024

(51) Int. Cl. H01L 21/66; H01L 23/00

(52) U.S. Cl. CPC H01L 22/12; H01L 24/80; H01L 2224/80895

(57) ABSTRACT

Aspects of the present disclosure provide a method for correcting an overlay error by shifting lithographic patterns to be formed on a wafer according to a bow measurement of the wafer. For example, the method can include receiving a first location at which one or more first semiconductor elements are to be formed on a first wafer, measuring the first wafer to identify a first bow measurement of the first wafer, calculating a second location that is shifted from the first location based on the first bow measurement, and forming the first semiconductor elements on the first wafer at the second location.

### FIELD OF THE INVENTION

The present disclosure relates to semiconductor fabrication, and, more particularly, to correction of design and mask shape position due to die and wafer distortion for bonding.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Exposure systems (also called tools) are used to implement photolithographic techniques. An exposure system typically includes an illumination system, a reticle (also called a photomask) or spatial light modulator (SLM) for creating a circuit pattern, a projection system, and a wafer alignment stage for aligning a photosensitive resist-covered semiconductor wafer. The illumination system illuminates a region of the reticle or SLM with a (preferably) rectangular slot illumination field. The projection system projects an image of the illuminated region of the reticle pattern onto the wafer. For accurate projection, it is important to expose a pattern of light on a wafer that is relatively flat or planar, preferably having less than 10 microns of height deviation. Bonding of two or more semiconductor wafers and/or dies offer higher performance for high density semiconductor devices.

### SUMMARY

Aspects of the present disclosure provide a method for correcting an overlay error by shifting lithographic patterns to be formed on a wafer according to a bow measurement of the wafer. For example, the method can include receiving a first location at which one or more first semiconductor elements are to be formed on a first wafer, measuring the first wafer to identify a first bow measurement of the first wafer, calculating a second location that is shifted from the first location based on the first bow measurement, and forming the first semiconductor elements on the first wafer at the second location.

In an embodiment, the method can further include receiving a third location at which one or more second semiconductor elements are to be formed on a second wafer, measuring the second wafer to identify a second bow measurement of the second wafer, calculating a fourth location that is shifted from the third location based on the second bow measurement, forming the second semiconductor elements on the second wafer at the fourth location, and bonding the first semiconductor elements to the second semiconductor elements. In another embodiment, the method can further include providing a second wafer having one or more second semiconductor elements formed thereon and bonding the first semiconductor elements to the second semiconductor elements.

In an embodiment, the method can further include providing a second wafer having one or more second semiconductor elements formed thereon, measuring the second wafer to identify a second bow measurement of the second wafer, and bonding the first semiconductor elements to the second semiconductor elements, wherein calculating the second location that is shifted from the first location based on the first bow measurement includes calculating the second location that is shifted from the first location based on the first bow measurement and the second bow measurement.

In an embodiment, calculating the second location that is shifted from the first location based on the first bow measurement can include calculating the second location that is shifted from the first location based on the first bow measurement and a thickness of the first wafer. In another embodiment, calculating the second location that is shifted from the first location based on the first bow measurement can include calculating the second location that is shifted from the first location based on the first bow measurement and a radius of the first wafer. In some embodiments, calculating the second location that is shifted from the first location based on the first bow measurement can include calculating the second location that is shifted from the first location based on the first bow measurement, a thickness of the first wafer, a distance between any neighboring two of the first semiconductor elements, and a radius of the first wafer.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A to 1C show first and second order bowing of a wafer;

FIGS. 2A and 2B show low order global wafer distortion and high order local wafer distortion, respectively;

FIG. 3 shows how wafer bow is defined;

FIGS. 4A-4C show shifting lithographic patterns to be formed on a wafer to correct an overlay error according to some embodiments of the present disclosure;

FIGS. 5A-5C show shifting lithographic patterns to be formed on two wafers and bonding the lithographic patterns to each other;

FIG. 6 is a flow chart of an exemplary method for correcting an overlay error by shifting lithographic patterns to be formed on a wafer according to a bow measurement of the wafer; and

FIG. 7 is a flow chart of an exemplary method for correcting an overlay error by shifting lithographic patterns to be formed on two wafers according to bow measurements of the two wafers and bonding the lithographic patterns to each other.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

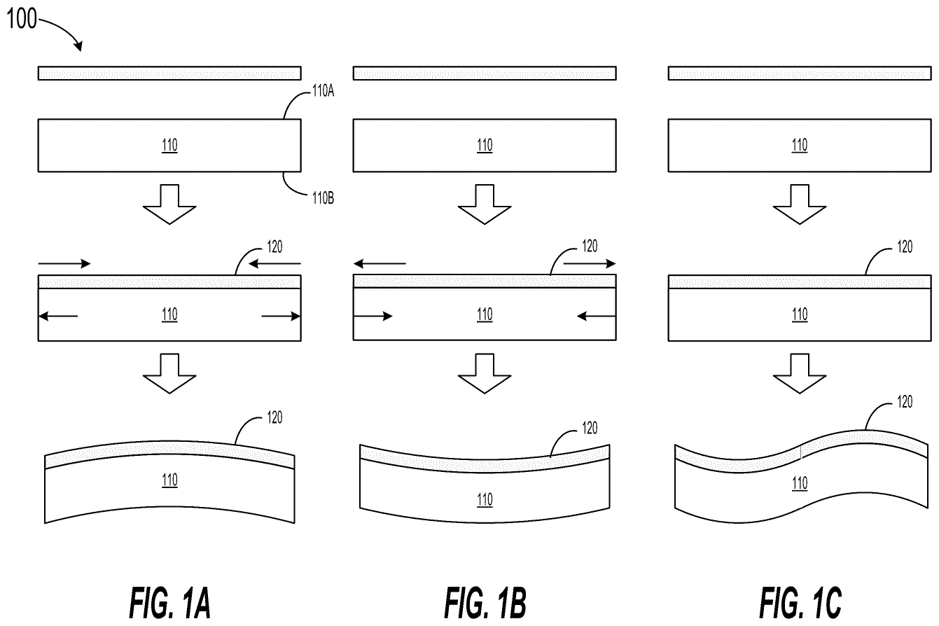

A functional semiconductor wafer can be comprised of the integration of over 70+ individual layers that ultimately culminate in functional devices. Each level requires multiple processing steps including, but not limited to thin film deposition, lithography and etches to form the desired structures. For example, microfabrication of a semiconductor structure 100 begins with a flat substrate or wafer 110, as those illustrated in FIGS. 1A to 1C. During microfabrication of the semiconductor structure 100, multiple processing steps are executed that can include depositing materials on the wafer 110, removing materials, implanting dopants, annealing, baking, and so forth. Almost any films deposited or grown on a wafer (e.g., the substrate 110) will be in a state of stress resulting from the difference between deposition temperature and room temperature (i.e., thermal stress) or from the growth or deposition conditions (i.e., intrinsic stress). Therefore, different materials and structural formations (or semiconductor elements) 120 thus formed can induce uniform or non-uniform wafer stresses, which result in bowing of the semiconductor structure 100.

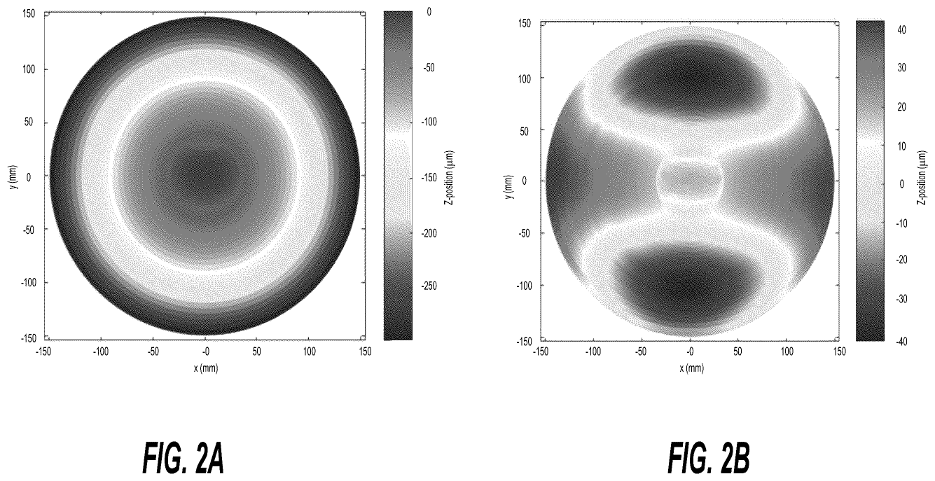

For example, FIGS. 1A and 1B show how the different materials and structural formations 120 can either induce a compressive or tensile stress in the wafer 110, respectively, resulting in first order bowing with bow measurements illustrating z-direction height (or z-height) deviations from a reference plane (not shown). As another example, FIG. 1C shows second order bowing of the wafer 110 with two bow measurements identifying positive and negative z-height deviations, respectively. The non-uniform wafer stresses fundamentally distort the wafer grid. These distortions can manifest as low order global spherical type deformations as depicted in FIG. 2A, which shows z-height variations on 300 nm semiconductor wafers. Higher order localized z-height variations may exist as stand-alone distortions or may be embedded in the global signature. An example of a higher order wafer deformation is presented in FIG. 2B. The data presented is derived from standard semiconductor metrology equipment common to the industry.

The wafer 110 can be measured by a bow measurement device to identify bow measurement of the wafer 110. In an embodiment, the bow measurement device can use optical (e.g., using a scanning laser technique), capacitance-based, acoustic and other mechanisms to measure the z-direction height deviations across a surface of the wafer 110 and store the height deviations by (x, y) coordinates. The z-direction height deviations can be mapped at various resolutions depending on type of metrology equipment used and/or a resolution desired. The bow measurement can include raw bow data or be represented as a bow signature with relative values. In an embodiment, the wafer 110 has a working surface 110A, on which the different materials and structural formations 120 can be formed, and a backside surface 110B opposite to the working surface 110A, as shown in FIG. 1A. The wafer 110 may have an amount of wafer bow as a result from one or more micro fabrication processing steps that have been executed to create at least part of a semiconductor structure, e.g., the semiconductor structure 100, on the working surface 110A of the wafer 110. For example, transistor gates may be completed or only partially completed.

Curvature K is the inverse of the curvature radius R of a wafer. A total curvature K of one or more layers (e.g., the different materials and structural formations 120) on a wafer (e.g., the substrate 110) can be the sum of the individual curvatures Kᵢ induced by each of the layers (See Townsend, P. H.; Barnett, D. M.; Brunner, T. A. Elastic relationships in layered composite media with approximation for the case of thin films on a thick substrate. J. Appl. Phys. 1987, 62, 4438-4444). Stresses in the substrate 110 (σₛ) and in each of the layers (σᵢ) can be expressed in function of these curvatures (e.g., K and Kᵢ), respectively, as follows:

$${σ}_{s} = \frac{{E}_{s}}{1 - {v}_{s}} ( \frac{{t}_{s}}{3} - z ) K \qquad ( 1 )$$

$${σ}_{i} = \frac{1}{6} \frac{{E}_{i}}{1 - {v}_{i}} ( \frac{{t}_{s}^{2}}{{t}_{i}} ) ( {K}_{i} - {K}_{i - 1} ) \qquad ( 2 )$$

where subscripts i and s refer to the layer i and the substrate, respectively, E represents the Young modulus, v represents the Poisson ratio, E/(1−v) is the biaxial elastic modulus, tᵢ and tₛ are the layer and substrate thicknesses, respectively, z is the coordinate distance normal to the linear dimension of the composite and calculated from the backside surface of the substrate (the layer i is formed on the frontside surface of the substrate), and Kᵢ₋₁ and Kᵢ are the curvature of the wafer before and after deposition of the layer i, respectively. Formulas (1) and (2) are valid when the substrate is much thicker than the layer i, tᵢ<<tₛ.

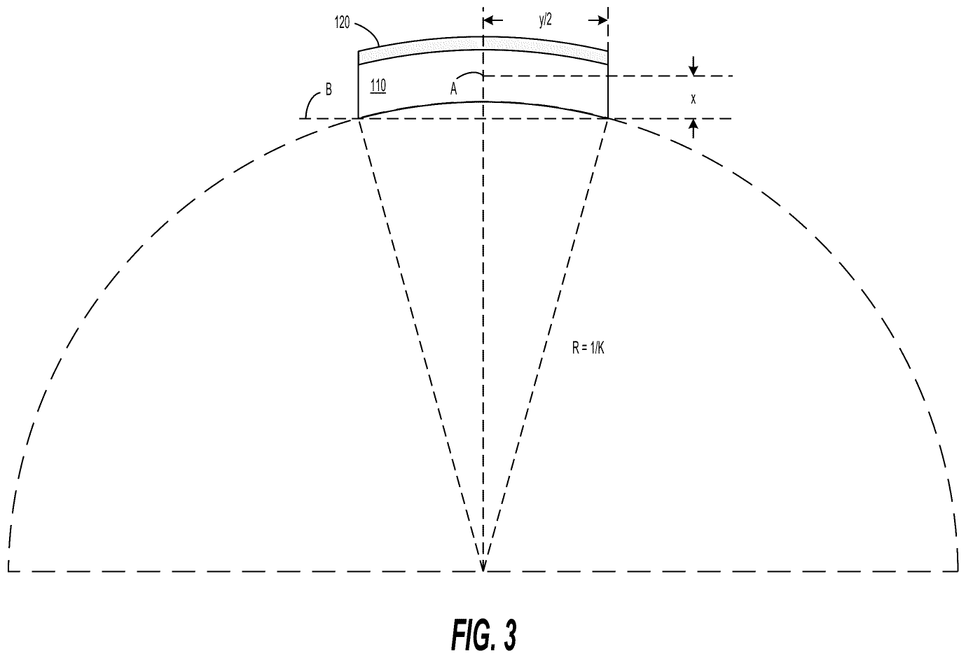

Formulas (1) and (2) can be simplified to give a direct relation between stress and bow x. As shown in FIG. 3 (where

$${R}^{2} = {( \frac{y}{2} )}^{2} + {( R - x )}^{2} ) ,$$

bow x can be defined as the distance between the point at mid-thickness and wafer center (denoted by “A”) and a reference plane (denoted by “B”) defined by three points at the wafer edges. The stress-thickness product of layer i can be proportional to the bow difference xᵢ and xᵢ₋₁ (or Δₓ) before and after the deposition of layer i:

$${σ}_{s} {t}_{i} = - {β}_{s} ( {x}_{i} - {x}_{i - 1} ) \qquad ( 3 )$$

with

$${β}_{s} = \frac{4}{3} \frac{{E}_{s}}{1 - {v}_{s}} {( \frac{{t}_{s}}{{y}_{s}} )}^{2} , \qquad ( 4 )$$

where βₛ is a parameter depending only on the substrate and represents its rigidity, the minus sign coming from the definition of bow, as negative for tensile stress and positive for compressive stress.

Wafer bow (or curvature) has at least two consequences on the fabrication of the wafer. Wafer bow is a signature of stress in the wafer and in the layers formed thereon and may cause the wafer to break. For example, the increase in bow as the wafer is thinned will increase the likelihood of wafer breakage. Wafer bow can also make some impacts on photolithography, e.g., out-of-plane distortion (OPD, or bow) translating into in-plane-distortion (IPD). For example, the bowing of the semiconductor structure 100 due to the formation of the different materials and structural formations 120 on the wafer 110 can affect overlay and typically results in overlay errors of various magnitudes.

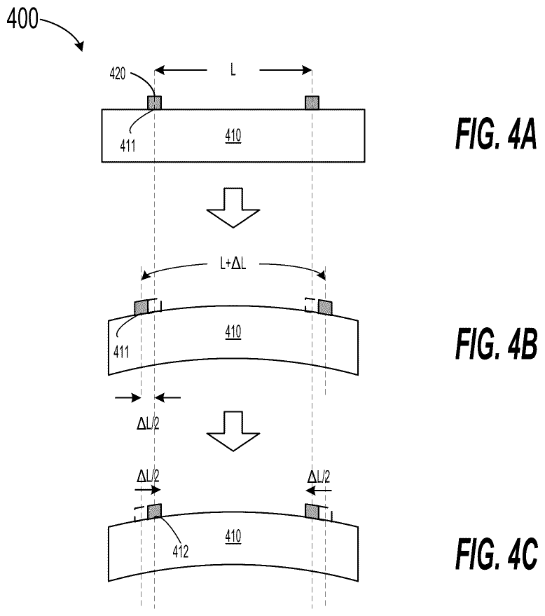

As shown in FIG. 4A, a semiconductor structure 400 includes a substrate (or a wafer) 410 that is planar. In an embodiment, semiconductor elements 420 (e.g., bonding pads) are to be formed on the planar substrate 410. As shown in FIG. 4A, the two bonding pads 420 are designed to be formed on the planar substate 410 at a first location 411 and be separated by a distance L. In an embodiment, the two bonding pads 420, after being formed on the substrate 410, are to be bonded to another two bonding pads formed on another substrate. However, before the bonding pads 420 are formed on the substrate 410, the substrate 410 may be bowed and distorted, for example, due to the formation of the different materials and structure formations 120, and, as a result, the two bonding pads 420 that are formed on the substate 410 at the first location 411 may be misaligned with the another two bonding pads. For example, the two bonding pads 420 may be separated farther, e.g., by another distance L+ΔL (or separated nearer, e.g., by a distance L−ΔL), as shown in FIG. 4B. The in-plane-distortion ΔL can be calculated as follows:

$$Δ {L}_{s ( N + 1 )} = - \frac{{t}_{s} L}{6} ( {K}_{N + 1} - {K}_{N} ) , \qquad ( 5 )$$

which indicates that the in-plane-distortion ΔL_{s(N+1)} at step N+1 of two semiconductor elements (e.g., the bonding pads 420) separated by the distance L is proportional to the wafer (i.e., the substrate 410) thickness tₛ and the difference between the curvature K_{N+1} at step N+1 and the curvature K_{N} at step N (See Turner, K. T.; Veeraraghavan, S., Sinha, J. K. Relationship between localized wafer shape changes induced by residual stress and overlay errors. J. Micro Nanolithography MEMS MOEMS 2012, 11, 013001). Given that the substrate 410 is much thicker than the different materials and structure formations 120 (that cause the substrate 410 to bow), that is tᵢ<<tₛ, the in-plane-distortion ΔL can be calculated as a function of the wafer bow difference Δₓ:

$$Δ {L}_{s ( N + 1 )} = - \frac{4}{3} \frac{{t}_{s} L}{{y}^{2}} {Δ}_{x} . \qquad ( 6 )$$

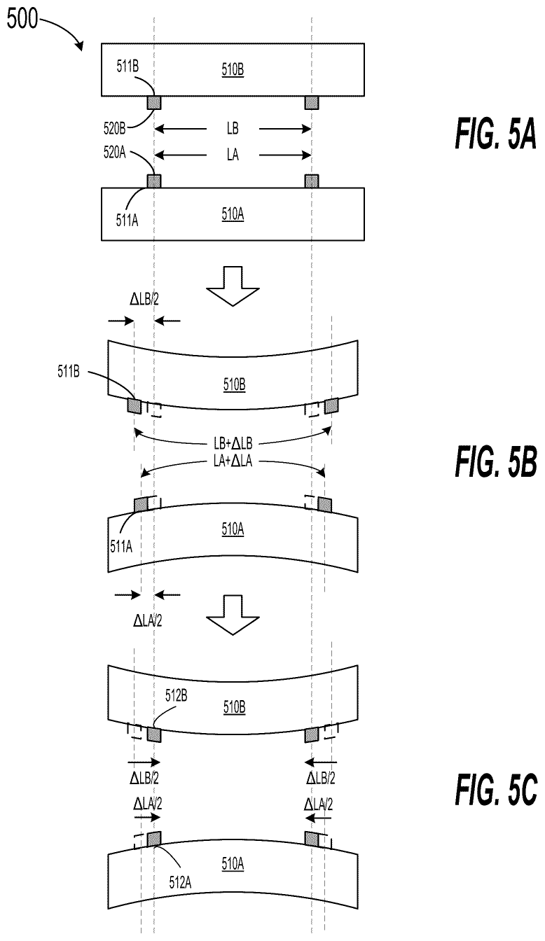

Therefore, the total overlay error can be estimated in function of wafer bow difference between two photolithography levels. After the in-plane-distortion ΔL is calculated, the bonding pads 420 can be formed on the substrate 410 at a second location 412 that is shifted from the first location 411 by ΔL/2 to correct the overlay error, as shown in FIG. 4C.
The semiconductor structure 400 having the bonding pads 420 formed on the substrate 410 can be bonded to another semiconductor structure that has bonding pads formed on another substrate of the another semiconductor structure. As shown in FIG. 5A, first semiconductor elements (e.g., two first bonding pads) 520A are to be formed on a first substrate (or a first wafer) 510A (that is planar, for example), and second semiconductor elements (e.g., two second bonding pads) 520B are to be formed on a second substrate (or a second wafer) 510B (that is planar, for example). As shown in FIG. 5A, the two first bonding pads 520A are designed to be formed on the planar substate 510A at a first location 511A and be separated by a first distance LA, and the two second bonding pads 520B are designed to be formed on the planar substate 510B at a third location 511B and be separated by a second distance LB. In an embodiment, the two first bonding pads 520A, after being formed on the first substrate 510A, are to be bonded to the two second bonding pads 520B formed on the second substrate 510B. However, before the two first bonding pads 520A are formed on the first substrate 510A, the first substrate 510A may be bowed and distorted, for example, due to the formation of the different materials and structure formations 120, and, as a result, the two first bonding pads 520A that are formed on the first substate 510A at the first location 511A may be misaligned with the two second bonding pads 520B to be formed on the second substrate 510B. For example, the two first bonding pads 520A may be separated farther, e.g., by another first distance LA+ΔLA (or separated nearer, e.g., by a distance LA−ΔLA), as shown in FIG. 5B. Similarly, before the two second bonding pads 520B are formed on the second substrate 510B, the second substrate 510B may be bowed and distorted, for example, due to the formation of the different materials and structure formations 120, and, as a result, the two second bonding pads 520B that are formed on the second substate 510B at the third location 511B may be misaligned with the two first bonding pads 520A. For example, the two second bonding pads 520B may be separated farther, e.g., by another second distance LB+ΔLB (or separated nearer, e.g., by a distance LA−ΔLA), as shown in FIG. 5B. After the first in-plane-distortion ΔLA is calculated, the first bonding pads 520A can be formed on the first substrate 510A at a second location 512A that is shifted from the first location 511A by ΔLA/2 to correct the overlay error, as shown in FIG. 5C. Similarly, after the second in-plane-distortion ΔLB is calculated, the second bonding pads 520B can be formed on the second substrate 510B at a fourth location 512B that is shifted from the third location 511B by ΔLB/2 to correct the overlay error, as shown in FIG. 5C. Therefore, the two first bonding pads 520A can be aligned with and bonded to the two second bonding pads 520B, respectively.

In another embodiment, either the first bonding pads 520A or the second bonding pads 520B can be formed on the first substrate 510A or the second substrate 510B, respectively, at a fifth location that is shifted from the first location 511A or the third location 511B based on the first in-plane-distortion ΔLA and the second in-plane-distortion ΔLA. For example, the first bonding pads 520A can be formed on the first substrate 510A at the fifth location that is shifted from the first location 511A by the absolute value of (ΔLB/2−ΔLA/2), and the second bonding pads 520B can be formed on the second substrate 510B still at the third location 511B. Therefore, the first bonding pads 520A and the second bonding pads 520B can still be aligned with each other.

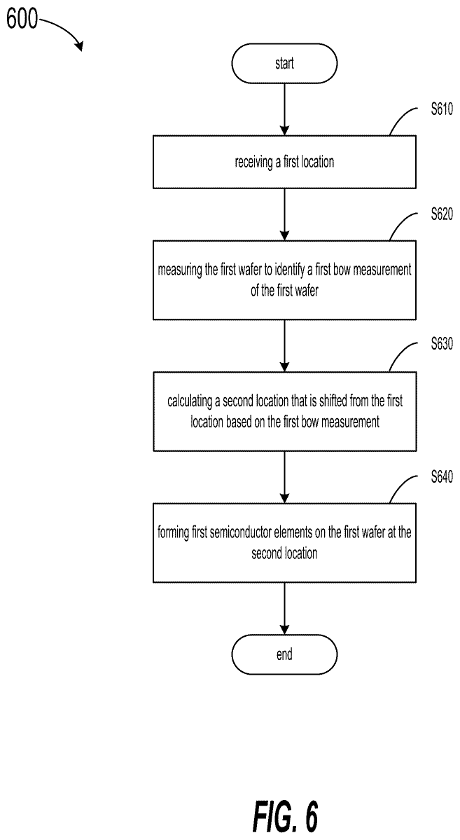

FIG. 6 is a flow chart of an exemplary method 600 for correcting an overlay error by shifting semiconductor elements (e.g., lithographic patterns such as bonding pads) according to formula (6). In various embodiments, some of the steps of the method 600 shown can be performed concurrently or in a different order than shown, can be substituted by other method steps, or can be omitted. Additional method steps can also be performed as desired. The method 600 can start at step S610.

At step S610, a first location (e.g., the first location 411 shown in FIG. 4A or the first location 511A shown in FIG. 5A) can be received. In an embodiment, one or more first semiconductor elements (e.g., the semiconductor elements 420 shown in FIG. 4A or the first semiconductor elements 520A shown in FIG. 5A) can be formed on a first wafer (e.g., the substrate 410 shown in FIG. 4A or the first substrate 510A shown in FIG. 5A) at the first location. The method 600 can proceed to step S620.

At step S620, the first wafer can be measured to identify a first bow measurement of the first wafer. In an embodiment, the bow measurement device can use optical (e.g., using a scanning laser technique), capacitance-based, acoustic and other mechanisms to measure the first wafer to identify the first bow measurement (e.g., the z-direction height deviations across a surface) of the first wafer and store the height deviations by (x, y) coordinates. The method 600 can proceed to step S630.

At step S630, a second location that is shifted from the first location can be calculated based on the first bow measurement. In an embodiment, the second location that is shifted from the first location can be calculated based on the first bow measurement, a thickness of the first wafer (tₛ), a distance between any neighboring two of the first semiconductor elements (L), and a radius of the first wafer that is bowed

$$( \frac{y}{2} ) ,$$

as indicated by formula (6). The method 600 can proceed to step S640.

At step S640, the first semiconductor elements can be formed on the first wafer at the second location.

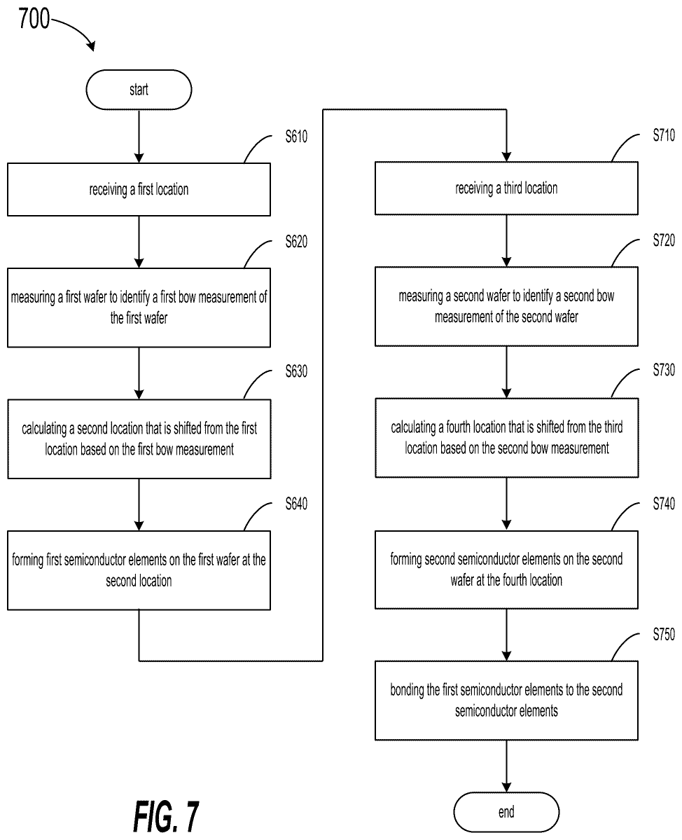

FIG. 7 is a flow chart of an exemplary method 700 for correcting an overlay error by shifting semiconductor elements (e.g., lithographic patterns such as bonding pads) formed on two wafers according to formula (6) and bonding the bonding pads form on the two wafers to each other. In various embodiments, some of the steps of the method 700 shown can be performed concurrently or in a different order than shown, can be substituted by other method steps, or can be omitted. Additional method steps can also be performed as desired. The method 700 can include steps S610 to S640. The method 700 can proceed to step S710.

At step S710, a third location (e.g., the third location 511B shown in FIG. 5A) can be received. In an embodiment, one or more second semiconductor elements (e.g., the second semiconductor elements 520B shown in FIG. 5A) can be formed on a second wafer (e.g., the second substrate 510B shown in FIG. 5A) at the third location. The method 700 can proceed to step S720.

At step S720, the second wafer can be measured to identify a second bow measurement of the second wafer. In an embodiment, the bow measurement device can use optical (e.g., using a scanning laser technique), capacitance-based, acoustic and other mechanisms to measure the second wafer to identify the second bow measurement. The method 700 can proceed to step S730.

At step S730, a fourth location that is shifted from the third location can be calculated based on the second bow measurement. In an embodiment, the fourth location that is shifted from the third location can be calculated based on the second bow measurement, a thickness of the second wafer (tₛ), a distance between any neighboring two of the second semiconductor elements (L), and a radius of the second wafer that is bowed

$$( \frac{y}{2} ) ,$$

as indicated by formula (6). The method 700 can proceed to step S740.

At step S740, the second semiconductor elements can be formed on the second wafer at the fourth location. Therefore, the first semiconductor elements and the second semiconductor elements can be aligned with each other. The method 700 can proceed to step S750.

At step S750, the first semiconductor elements can be bonded to the second semiconductor elements.

In the example embodiment shown FIG. 7, the first semiconductor elements can be formed on the second wafer at the second location that is shifted from the first location, and the second semiconductor element can be formed on the second wafer at the fourth location that is shifted from the third location. In another embodiment, either the first semiconductor elements or the second semiconductor elements can be formed on the first wafer or the second wafer, respectively, at a fifth location that is shifted from the first location or the third location based on the first in-plane-distortion ΔLA and the second in-plane-distortion ΔLA (or the first bow measurement and the second bow measurement). For example, the first semiconductor elements can be formed on the first wafer at the fifth location that is shifted from the first location by the absolute value of (ΔLB/2−ΔLA/2), and the second semiconductor elements can be formed on the second wafer still at the third location. Therefore, the first semiconductor elements and the second semiconductor elements can still be aligned with each other.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
receiving a first location at which one or more first semiconductor elements are to be formed on a first wafer;
measuring the first wafer to identify a first bow measurement of the first wafer;
calculating a second location that is shifted from the first location based on the first bow measurement; and
forming the first semiconductor elements on the first wafer at the second location.

2. The method of claim 1, further comprising:
receiving a third location at which one or more second semiconductor elements are to be formed on a second wafer;
measuring the second wafer to identify a second bow measurement of the second wafer;
calculating a fourth location that is shifted from the third location based on the second bow measurement;
forming the second semiconductor elements on the second wafer at the fourth location; and
bonding the first semiconductor elements to the second semiconductor elements.

3. The method of claim 1, further comprising:
providing a second wafer having one or more second semiconductor elements formed thereon;
measuring the second wafer to identify a second bow measurement of the second wafer; and
bonding the first semiconductor elements to the second semiconductor elements,
wherein calculating the second location that is shifted from the first location based on the first bow measurement includes calculating the second location that is shifted from the first location based on the first bow measurement and the second bow measurement.

4. The method of claim 1, wherein calculating the second location that is shifted from the first location based on the first bow measurement includes calculating the second location that is shifted from the first location based on the first bow measurement and a thickness of the first wafer.

5. The method of claim 1, wherein calculating the second location that is shifted from the first location based on the first bow measurement includes calculating the second location that is shifted from the first location based on the first bow measurement and a radius of the first wafer.

6. The method of claim 1, wherein calculating the second location that is shifted from the first location based on the first bow measurement includes calculating the second location that is shifted from the first location based on the first bow measurement, a thickness of the first wafer, a distance between any neighboring two of the first semiconductor elements, and a radius of the first wafer.

7. The method of claim 1, further comprising:
providing a second wafer having one or more second semiconductor elements formed thereon; and
bonding the first semiconductor elements to the second semiconductor elements.

8. The method of claim 1, wherein the first semiconductor elements include bonding pads.
